(19) United States
(12) Patent Application Publication
(10) Pub. No.: US 2025/0348225 A1
(43) Pub. Date: Nov. 13, 2025

(54) Data Storage Device and Method for Predictive Read Threshold Calibration

(71) Applicant: Sandisk Technologies, Inc., Milpitas, CA (US)

(72) Inventors: Ariel Navon, Revava (IL); David Avraham, San Jose, CA (US); Alexander Bazarsky, Holon (IL); Eran Sharon, Rishon Lezion (IL)

(73) Assignee: Sandisk Technologies, Inc., Milpitas, CA (US)

(21) Appl. No.: 18/658,074

(22) Filed: May 8, 2024

(51) Int. Cl. G06F 3/06

(52) U.S. Cl. CPC G06F 3/0616; G06F 3/0635; G06F 3/0659; G06F 3/0679

(57) ABSTRACT

A predictive read threshold calibration method is provided in which a dedicated hardware module is used for read threshold calibration. The hardware module uses a tree-based inferencing model to generate trees that produce respective inference results based on a plurality of read thresholds. An inferred read threshold is obtained by summing the inference results of the trees, and the memory is read using the inferred read threshold. Other embodiments are provided.

### BACKGROUND

One of the main challenges introduced by NAND process shrinking and three-dimensional stacking is maintaining process uniformity. In addition, data storage devices may need to support a wide range of operational conditions (such as different program/erase cycles, retention times, and temperatures), which can lead to increased variability between memory dies, blocks, and pages across the different operational conditions. Due to these variations, the read thresholds (RT) used for reading a memory page in some data storage devices are not fixed and can change significantly as a function of the physical location and the operational conditions, especially for less-mature memory nodes.

### BRIEF DESCRIPTION OF THE DRAWINGS

FIG. 1A is a block diagram of a data storage device of an embodiment.

FIG. 1B is a block diagram illustrating a storage module of an embodiment.

FIG. 1C is a block diagram illustrating a hierarchical storage system of an embodiment.

FIG. 2A is a block diagram illustrating components of the controller of the data storage device illustrated in FIG. 1A according to an embodiment.

FIG. 2B is a block diagram illustrating components of the data storage device illustrated in FIG. 1A according to an embodiment.

FIG. 3 is a block diagram of a host and a data storage device of an embodiment.

FIG. 4 is an illustration of a storage controller of an embodiment.

FIG. 5 is a flow chart of a method of an embodiment that is performed after a read threshold calibration operation is initiated.

FIG. 6 is a flow chart of a method of an embodiment for predictive read threshold calibration.

FIG. 7 is a graph of an embodiment of a failed bit count (FBC) Sigma plot as a function of a number of trees.

### DETAILED DESCRIPTION

The following embodiments generally relate to a data storage device and method for predictive read threshold calibration. In one embodiment, a data storage device is provided comprising a memory and one or more processors. The one or more processors, individually or in combination, are configured to: use a tree-based inferencing model to generate a plurality of trees, wherein each tree produces an inference result based on a plurality of read thresholds; obtain an inferred read threshold by summing the inference results of the plurality of trees; and read the memory using the inferred read threshold.

In another embodiment, a method is provided that is performed in a data storage device comprising a memory. The method comprises: analyzing operating conditions and/or available resources of the data storage device; based on the analyzing, determining a number of single read threshold operations; operating a read threshold calibration unit the determined number of times to provide a read threshold calibration result; and reading the memory using the read threshold calibration result.

In yet another embodiment, a data storage device is provided comprising a memory and means for: operating a read threshold calibration unit of the data storage device a plurality of times to provide a read threshold calibration result, wherein the plurality of times is based on operating conditions and/or available resources of the data storage device; and reading the memory using the read threshold calibration result.

Other embodiments are possible, and each of the embodiments can be used alone or together in combination. Accordingly, various embodiments will now be described with reference to the attached drawings.

### Embodiments

The following embodiments relate to a data storage device (DSD). As used herein, a “data storage device” refers to a non-volatile device that stores data. Examples of DSDs include, but are not limited to, hard disk drives (HDDs), solid state drives (SSDs), tape drives, hybrid drives, etc. Details of example DSDs are provided below.

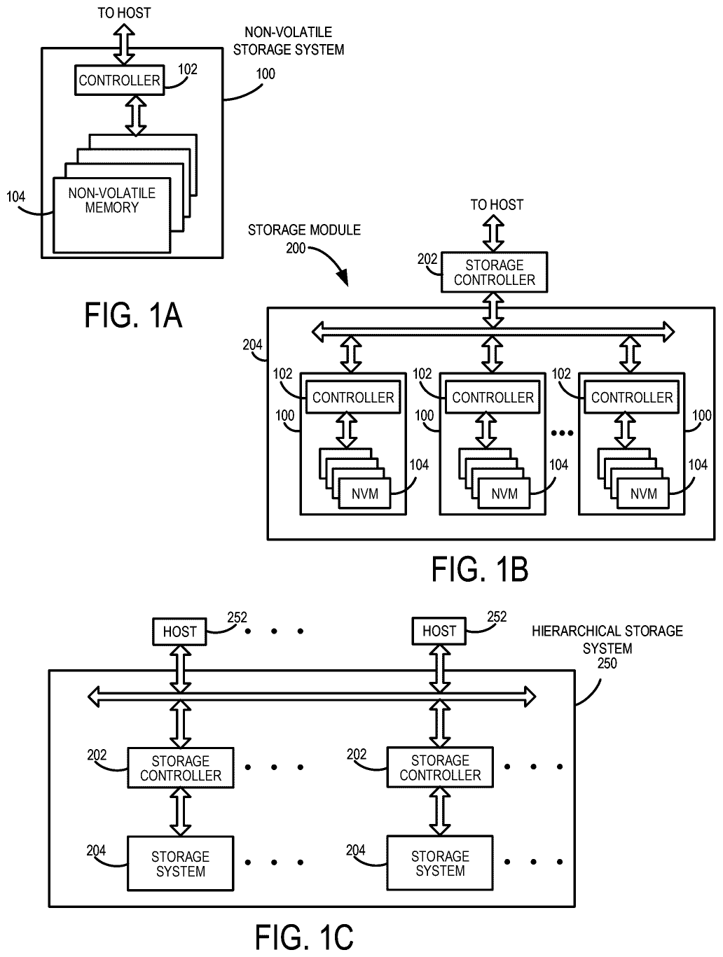

Examples of data storage devices suitable for use in implementing aspects of these embodiments are shown in FIGS. 1A-1C. It should be noted that these are merely examples and that other implementations can be used. FIG. 1A is a block diagram illustrating the data storage device 100 according to an embodiment. Referring to FIG. 1A, the data storage device 100 in this example includes a controller 102 coupled with a non-volatile memory that may be made up of one or more non-volatile memory die 104. As used herein, the term die refers to the collection of non-volatile memory cells, and associated circuitry for managing the physical operation of those non-volatile memory cells, that are formed on a single semiconductor substrate. The controller 102 interfaces with a host system and transmits command sequences for read, program, and erase operations to non-volatile memory die 104. Also, as used herein, the phrase “in communication with” or “coupled with” could mean directly in communication/coupled with or indirectly in communication/coupled with through one or more components, which may or may not be shown or described herein. The communication/coupling can be wired or wireless.

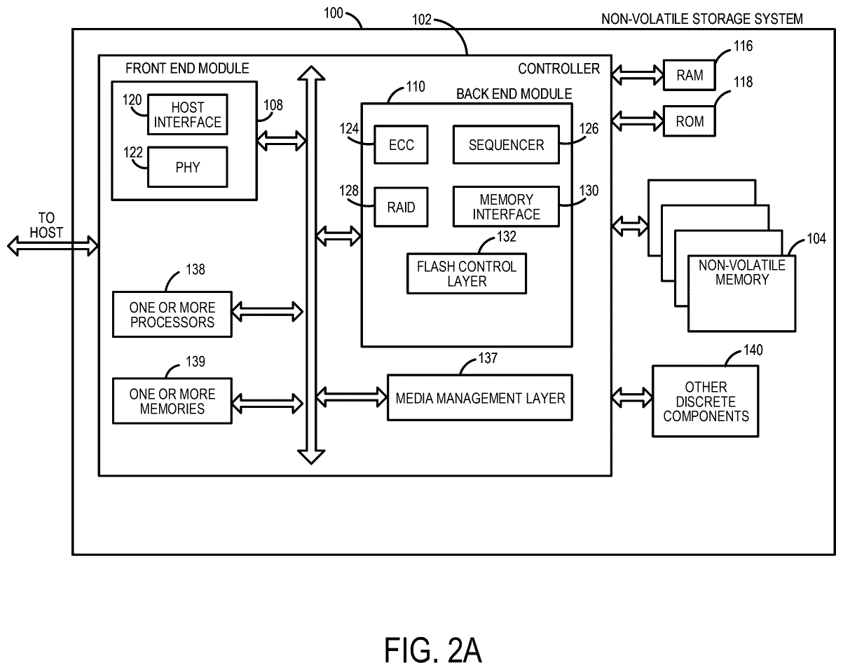

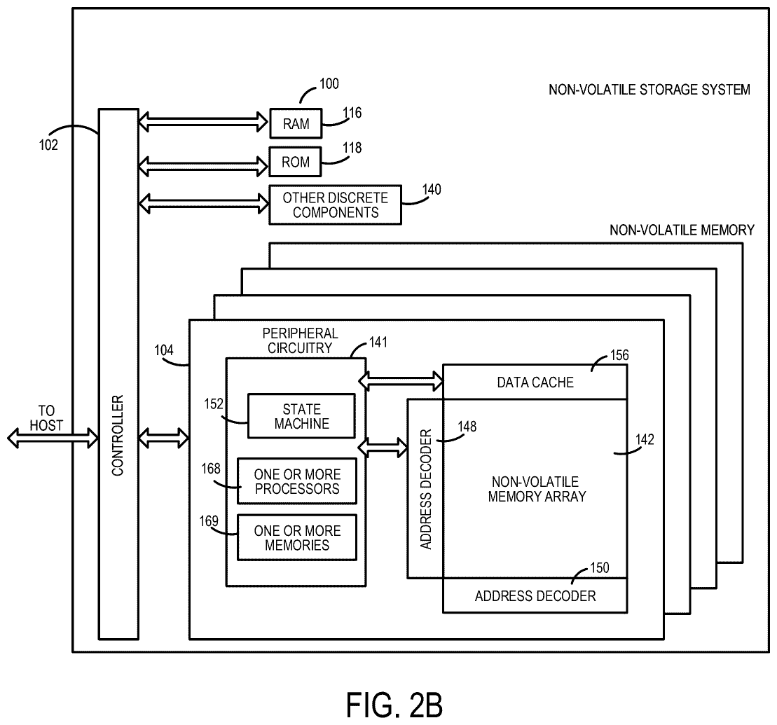

The controller 102 (which may be a non-volatile memory controller (e.g., a flash, resistive random-access memory (ReRAM), phase-change memory (PCM), or magnetoresistive random-access memory (MRAM) controller)) can include one or more components, individually or in combination, configured to perform certain functions, including, but not limited to, the functions described herein and illustrated in the flow charts. For example, as shown in FIG. 2A, the controller 102 can comprise one or more processors 138 that are, individually or in combination, configured to perform functions, such as, but not limited to the functions described herein and illustrated in the flow charts, by executing computer-readable program code stored in one or more non-transitory memories 139 inside the controller 102 and/or outside the controller 102 (e.g., in random access memory (RAM) 116 or read-only memory (ROM) 118). As another example, the one or more components can include circuitry, such as, but not limited to, logic gates, switches, an application specific integrated circuit (ASIC), a programmable logic controller, and an embedded microcontroller.

In one example embodiment, the non-volatile memory controller 102 is a device that manages data stored on non-volatile memory and communicates with a host, such as a computer or electronic device, with any suitable operating system. The non-volatile memory controller 102 can have various functionality in addition to the specific functionality described herein. For example, the non-volatile memory controller can format the non-volatile memory to ensure the memory is operating properly, map out bad non-volatile memory cells, and allocate spare cells to be substituted for future failed cells. Some part of the spare cells can be used to hold firmware (and/or other metadata used for housekeeping and tracking) to operate the non-volatile memory controller and implement other features. In operation, when a host needs to read data from or write data to the non-volatile memory, it can communicate with the non-volatile memory controller. If the host provides a logical address to which data is to be read/written, the non-volatile memory controller can convert the logical address received from the host to a physical address in the non-volatile memory. The non-volatile memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including resistive random-access memory (ReRAM), magnetoresistive random-access memory (MRAM), phase-change memory (PCM), NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC) (e.g., dual-level cells, triple-level cells (TLC), quad-level cells (QLC), etc.) or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, the data storage device 100 may be a card-based system, such as a secure digital (SD) or a micro secure digital (micro-SD) card. In an alternate embodiment, the data storage device 100 may be part of an embedded data storage device.

Although, in the example illustrated in FIG. 1A, the data storage device 100 (sometimes referred to herein as a storage module) includes a single channel between controller 102 and non-volatile memory die 104, the subject matter described herein is not limited to having a single memory channel. For example, in some architectures (such as the ones shown in FIGS. 1B and 1C), two, four, eight or more memory channels may exist between the controller and the memory device, depending on controller capabilities. In any of the embodiments described herein, more than a single channel may exist between the controller and the memory die, even if a single channel is shown in the drawings.

FIG. 1B illustrates a storage module 200 that includes plural non-volatile data storage devices 100. As such, storage module 200 may include a storage controller 202 that interfaces with a host and with data storage device 204, which includes a plurality of data storage devices 100. The interface between storage controller 202 and data storage devices 100 may be a bus interface, such as a serial advanced technology attachment (SATA), peripheral component interconnect express (PCIe) interface, double-data-rate (DDR) interface, or serial attached small scale compute interface (SAS/SCSI). Storage module 200, in one embodiment, may be a solid-state drive (SSD), or non-volatile dual in-line memory module (NVDIMM), such as found in server PC or portable computing devices, such as laptop computers, and tablet computers.

FIG. 1C is a block diagram illustrating a hierarchical storage system. A hierarchical storage system 250 includes a plurality of storage controllers 202, each of which controls a respective data storage device 204. Host systems 252 may access memories within the storage system 250 via a bus interface. In one embodiment, the bus interface may be a Non-Volatile Memory Express (NVMe) or Fibre Channel over Ethernet (FCOE) interface. In one embodiment, the system illustrated in FIG. 1C may be a rack mountable mass storage system that is accessible by multiple host computers, such as would be found in a data center or other location where mass storage is needed.

Referring again to FIG. 2A, the controller 102 in this example also includes a front-end module 108 that interfaces with a host, a back-end module 110 that interfaces with the one or more non-volatile memory die 104, and various other components or modules, such as, but not limited to, a buffer manager/bus controller module that manage buffers in RAM 116 and controls the internal bus arbitration of controller 102. A module can include one or more processors or components, as discussed above. The ROM 118 can store system boot code. Although illustrated in FIG. 2A as located separately from the controller 102, in other embodiments one or both of the RAM 116 and ROM 118 may be located within the controller 102. In yet other embodiments, portions of RAM 116 and ROM 118 may be located both within the controller 102 and outside the controller 102.

Front-end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, serially attached small computer system interface (SAS), Fibre Channel, universal serial bus (USB), PCIe, and NVMe. The host interface 120 typically facilitates transfer for data, control signals, and timing signals.

Back-end module 110 includes an error correction code (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the memory device 104. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. The controller 102 in this example also comprises a media management layer 137 and a flash control layer 132, which controls the overall operation of back-end module 110.

The data storage device 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller are optional components that are not necessary in the controller 102.

FIG. 2B is a block diagram illustrating components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including ReRAM, MRAM, PCM, NAND flash memory cells and/or NOR flash memory cells in a two-dimensional and/or three-dimensional configuration. Non-volatile memory die 104 further includes a data cache 156 that caches data and address decoders 148, 150. The peripheral circuitry 141 in this example includes a state machine 152 that provides status information to the controller 102. The peripheral circuitry 141 can also comprise one or more components that are, individually or in combination, configured to perform certain functions, including, but not limited to, the functions described herein and illustrated in the flow charts. For example, as shown in FIG. 2B, the memory die 104 can comprise one or more processors 168 that are, individually or in combination, configured to execute computer-readable program code stored in one or more non-transitory memories 169, stored in the memory array 142, or stored outside the memory die 104. As another example, the one or more components can include circuitry, such as, but not limited to, logic gates, switches, an application specific integrated circuit (ASIC), a programmable logic controller, and an embedded microcontroller.

In addition to or instead of the one or more processors 138 (or, more generally, components) in the controller 102 and the one or more processors 168 (or, more generally, components) in the memory die 104, the data storage device 100 can comprise another set of one or more processors (or, more generally, components). In general, wherever they are located and however many there are, one or more processors (or, more generally, components) in the data storage device 100 can be, individually or in combination, configured to perform various functions, including, but not limited to, the functions described herein and illustrated in the flow charts. For example, the one or more processors (or components) can be in the controller 102, memory device 104, and/or other location in the data storage device 100. Also, different functions can be performed using different processors (or components) or combinations of processors (or components). Further, means for performing a function can be implemented with a controller comprising one or more components (e.g., processors or the other components described above).

Returning again to FIG. 2A, the flash control layer 132 (which will be referred to herein as the flash translation layer (FTL) handles flash errors and interfaces with the host. In particular, the FTL, which may be an algorithm in firmware, is responsible for the internals of memory management and translates writes from the host into writes to the memory 104. The FTL may be needed because the memory 104 may have limited endurance, may be written in only multiples of pages, and/or may not be written unless it is erased as a block. The FTL understands these potential limitations of the memory 104, which may not be visible to the host. Accordingly, the FTL attempts to translate the writes from host into writes into the memory 104.

The FTL may include a logical-to-physical address (L2P) map (sometimes referred to herein as a table or data structure) and allotted cache memory. In this way, the FTL translates logical block addresses (“LBAs”) from the host to physical addresses in the memory 104. The FTL can include other features, such as, but not limited to, power-off recovery (so that the data structures of the FTL can be recovered in the event of a sudden power loss) and wear leveling (so that the wear across memory blocks is even to prevent certain blocks from excessive wear, which would result in a greater chance of failure).

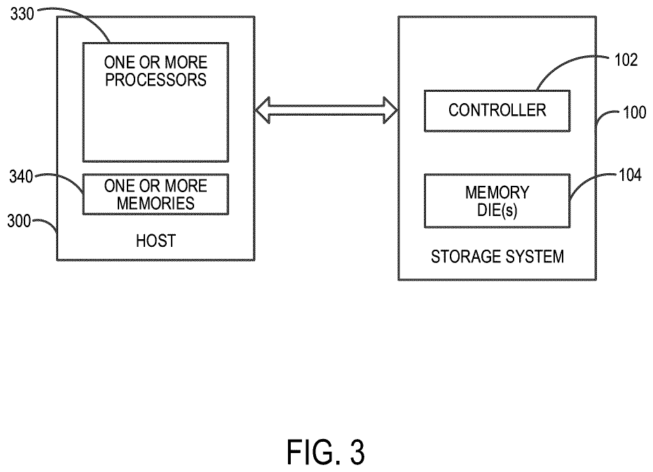

Turning again to the drawings, FIG. 3 is a block diagram of a host 300 and data storage device 100 of an embodiment. The host 300 can take any suitable form, including, but not limited to, a computer, a mobile phone, a tablet, a wearable device, a digital video recorder, a surveillance system, etc. The host 300 in this embodiment (here, a computing device) comprises one or more processors 330 and one or more memories 340. In one embodiment, computer-readable program code stored in the one or more memories 340 configures the one or more processors 330 to perform the acts described herein as being performed by the host 300. So, actions performed by the host 300 are sometimes referred to herein as being performed by an application (computer-readable program code) run on the host 300. For example, the host 300 can be configured to send data (e.g., initially stored in the host's memory 340) to the data storage device 100 for storage in the data storage device's memory 104.

As mentioned above, one of the main challenges introduced by NAND process shrinking and three-dimensional stacking is maintaining process uniformity. In addition, data storage devices may need to support a wide range of operational conditions (such as different program/erase cycles, retention times, and temperatures), which can lead to increased variability between memory dies, blocks, and pages across the different operational conditions. Due to these variations, the read thresholds (RT) used for reading a memory page in some data storage devices are not fixed and can change significantly as a function of the physical location and the operational conditions, especially for less-mature new memory nodes.

Reading with an inaccurate read threshold can leads to a higher bit error rate (BER), which can degrade performance and quality of service (QOS) due to decoding failures, which can require invoking high-latency recovery flows that can cause delays and hiccups in performance. The challenge of maintaining an optimal read threshold can be especially important for enterprise memory systems for which the quality-of-service requirements are very strict and for mobile, internet of things (IoT), and automotive memory systems for which the required range of operational conditions is wide and the frequency of condition changes (e.g., temperature) may be high. The problem is even more difficult during transitions to new, less-mature memory nodes.

Current solutions for read threshold calibration, such as BER estimation scan (BES) and valley search (VS), are high-latency operations aimed at optimizing read threshold for a specific wordline, which is good for rare read recovery flows in cases of failure to decode the data but may not be suitable for frequent operations in case of frequent read threshold changes. Hence, in order to cope with this issue, Flash memory systems can implement read threshold management schemes that try to track read threshold changes in the background via a maintenance process to ensure that appropriate read thresholds are used when the host issues a read command.

One approach is to track the read threshold per groups of blocks that share the same conditions. More specifically, blocks that are written roughly at the same time and temperature are grouped into time and temperature (TT) groups. Read thresholds are tracked for each time-and-temperature group, usually acquired on some representative wordline from a block within the group. When the host performs a read operation, the read threshold associated with the time-and-temperature group corresponding to the read block are used, where additional adaptation to the read threshold, according to the specific read wordline, is performed based on pre-calibrated wordline zoning tables.

Some read threshold management schemes may not adequately track the read threshold under frequently-changing conditions and high variations between memory pages. For example, U.S. patent application Ser. No. 17/838,481, filed Jun. 13, 2022, which is hereby incorporated by reference, describes a read threshold calibration method that applies a machine learning (ML) prediction model. More specifically, a system and method are described for inferring an optimal read threshold from all available information, including time-and-temperature group information, temperature information, BER information, program/erase count (PEC) information, and physical page location.

As another example, U.S. patent application Ser. No. 17/899,073, filed Aug. 30, 2022; Ser. No. 18/220,363, filed Jul. 11, 2023; and Ser. No. 18/242,061, filed Sep. 5, 2023, which are all hereby incorporated by reference, describe a method that allows for implementation of an inference engine for faster and more-accurate acquisition of read thresholds. This method uses a binary tree model to efficiently store only a subset of relevant correction data. In addition, the method does not need to directly read from the NAND memory to perform threshold calibrations. Hence, this method is much faster than BES\VS-based calibrations. The unique structure of the binary tree allows for a fast and low area and power solution, which can be implemented in hardware. However, a hardware implementation of a tree-based prediction model may not allow flexibility in a read threshold calibration engine and, therefore, may not be adapted to use cases that require a faster and a lower-power-consumption usage.

The following embodiments can address this problem by providing a modular design to calibrate read threshold using dedicated hardware (e.g., in a purely hardware implementation). In general, these embodiments can be used to provide a modular, binary trees hardware module for read threshold calibration. The modular design allows flexible usage with operation of different parts of the hardware engine in a way that will allow adaptive usage and optimize a tradeoff between accurately-provided read thresholds on one hand and latency and power consumption on the other hand. A purely hardware implementation refers to one that is implemented in hardware alone (e.g., in an application-specific integrated circuit (ASIC)) and not by executing software.

The basic hardware engine described in the patent applications mentioned above is based on using a non-linear function of multiple inputs that reflect current memory and data conditions. Previously, each operation of the hardware module required sequential operation of tree groups that compose the whole model (e.g., 15 consequent operations of four-tree groups at each step). The following embodiments allow a flexible operation of only part of these tree groups in accordance with user restrictions (e.g., either power and/or time/latency).

One embodiment is based on the nature of the construction of random-forest gradient boosting prediction models. These models are based on serial refinement of the predictions. At each new step during model training, a new tree is added under the metric of minimizing the error residual of the previous collection of trees. Therefore, in one example, a hardware model that implements M=60 trees—each collection of sub-group of m<M trees {1, 2, . . . , m} will provide more accurate read thresholds by its own. As m gets larger and includes more trees, the eventually-predicted read thresholds will be more accurate.

So, these embodiments provide a flexible usage of the hardware module where the number of operated trees can be set adaptively in accordance with user requirements or set automatically by tracking system conditions and available resources (e.g., current power consumptions, PEC value, system temperature, etc.). These embodiments allow for providing more-accurate thresholds at the expense of investing more time and power in the inference engine operation. For example, in cases of high system temperature, performance throttling may be applied in order to avoid further heating, thus allowing more bandwidth/trim for the read threshold inference operation that may use the full tree-based model (e.g., 60 trees). At the same time, in such conditions of high temperature, Xtemp effects may result in elevated BER, which may require more-accurate read thresholds in order to maintain low BER levels and avoid high error correction code (ECC) decoding latency and power that may further increase system temperature or even an ECC decoding failure. Thus, at high system temperature, it may be beneficial to use the full inference model to obtain an accurate read threshold. Indeed, the system may allow the latency for a full inference model application due to performance throttling. At a normal system temperature, the data storage device may use an inference according to a reduced/more-limited model (e.g., a smaller number (such as <60) trees) to enable inferencing at a rate that does not limit full system performance (with small/low-complexity inferencing hardware) while providing sufficiently good read thresholds under normal temperature conditions.

In one embodiment, the hardware module may implement a tree-based inferencing model capable of simultaneous calculation of k trees. Each tree produces an inference results on all the read thresholds. In this embodiment, if the storage design operates on quad-level cell (QLC) memory, the number of calibrated read thresholds in the hardware unit would be 2⁴−1=15. If the storage design operates on triple-level cell (TLC) memory, the number of calibrated read thresholds would be 2³−1=7, and so on. The final inference result can be obtained by summing up the results of the individual trees.

The hardware module may be activated once to produce an inference result based on k trees with minimal latency. Alternatively, it can be activated twice in order to produce a more-accurate inference result based on 2*k trees at the expense of 2× latency. Alternatively, it can be activated m times in order to produce an even more accurate inference result based on m*k trees at the expense of m times the latency. The number of times the read threshold calibration hardware operates can affect the accuracy of the total calibration operation. It can depend on different system factors such as, but not limited to, PEC, environment conditions, a performance requirement, available resources, and system temperature. When accuracy is needed more, the data storage device can operate the hardware more times. When accuracy is less required or resources are scarce, only a single operation can be performed.

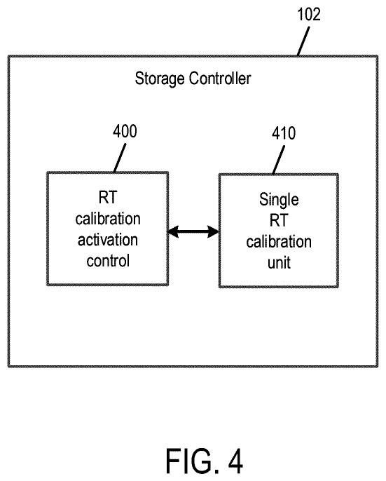

Turning again to the drawings, FIG. 4 is an illustration of a storage controller 102 of an embodiment. As shown in FIG. 4, in this embodiment, the storage controller 102 comprises a read threshold calibration activation control unit 400 and a single read threshold calibration unit 410, both of which can be implemented by one or more processors of the controller 102, as discussed above. The read threshold calibration activation control unit 400 may operate the single read threshold calibration unit 410 according to its consideration.

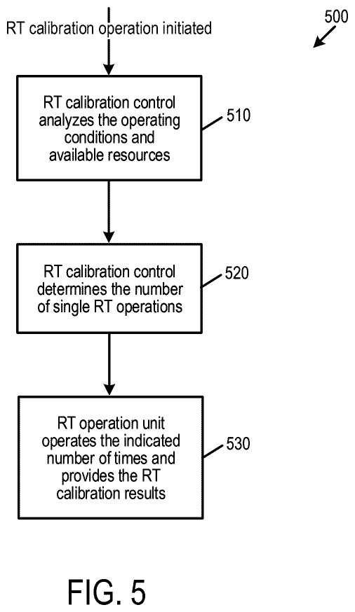

FIG. 5 is a flow chart 500 of a method of an embodiment that is performed after a read threshold calibration operation is initiated. As shown in FIG. 5, in this method, the read threshold calibration activation control unit 400 analyzes the operating conditions and available resources (act 510) and then determines the number of single read threshold operations (act 520). Next, the single read threshold calibration unit 410 operates the indicated number of times and provides the read threshold calibration results (act 530).

In another embodiment, the read threshold activation control unit 400 can either decide on the number of activation times before the entire calibration operation or on-the-fly based on the feedback from the read threshold calibration unit 410. For example, if the change magnitude of the read threshold is large (i.e., above a certain threshold), there may be more merit to additional activations of the calibration unit to refine the results as the optimal read threshold are far from the current read threshold. More specifically, the tree-based model can be trained such that each tree corrects for the residual error of the inference model based on the previous trees. In this case, the correction applied by each consecutive tree is expected to be of lower magnitude. Hence, the decision on the number of trees applied in a specific inferencing operation may be dynamic based on the magnitude of correction introduced by the last set of k trees that was calculated in the previous round. Once the magnitude of correction drops below a predefined threshold, the inferencing operation can be deemed as accurate enough and terminated. In addition, if the conditions or available resources change during the operation of the calibration, the ability to terminate or reduce the number of operation times is provided with this scheme.

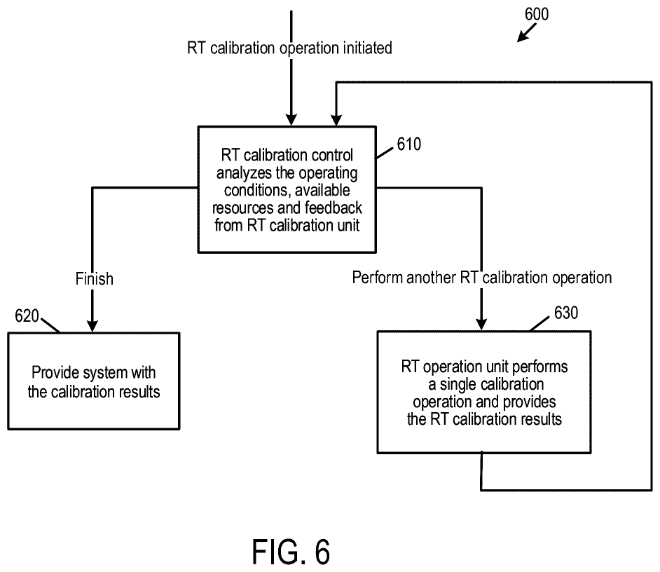

FIG. 6 is a flow chart 600 of a method of an embodiment that is performed after a read threshold calibration operation is initiated. In this method, after each iteration of the read threshold calibration unit 410, the read threshold calibration control unit 400 can decide to terminate the operation or resume to another calibration unit iteration. More specifically, as shown in FIG. 6, in this method, the read threshold calibration activation control unit 400 analyzes the operating conditions, available resources, and feedback from the read threshold calibration unit 410 (act 610). If the read threshold calibration activation control unit 400 concludes, based on this analysis, that the read threshold calibration operation is finished, the read threshold calibration activation control unit 400 provides the system with the calibration results (act 620). However, if the read threshold calibration activation control unit 400 concludes that another read threshold calibration operation is to be performed, the read threshold calibration unit 410 performs a single calibration operation and provides the read threshold calibration results.

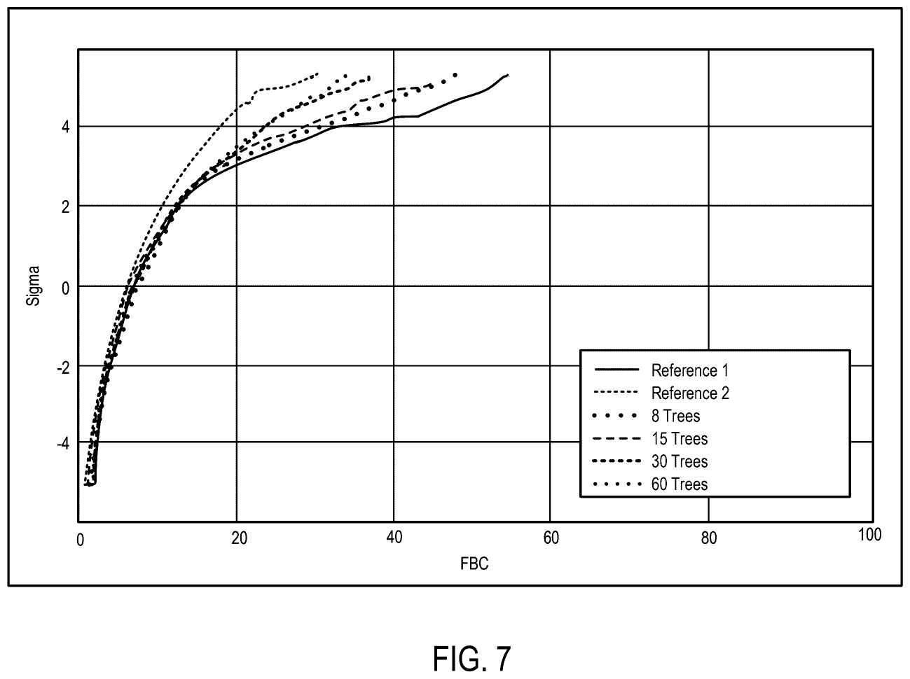

In yet another embodiment, the read threshold operation unit may consist of a single read threshold calibration. The logic behind this embodiment is that some read thresholds may require a more-extensive operation (e.g., more calibration iterations) due to a larger Vt-shift of the read threshold, while other read thresholds may require a lower number of calibration iterations. For example, in TLC memory, the F-G threshold is known to incur larger Vt shift compared to the other read thresholds due to external conditions such as Xtemp or DR. Using this embodiment, the F-G RT calibration may run several more iterations than the A-B RT calibration due to the need for a finer result. Example results of the operation are shown in the graph of FIG. 7, which shows a comparison between operating over 60 trees versus shorter models. Thus, FIG. 7 shows the impact of the number of trees used in the model on the failed bit count (FBC) levels. This figure is of the lower page of a BiCS5-based memory.

One line is the FBC level when using BES for each and every point. Another line is the FBC level when using certain read thresholds. All the lines in between depict various models varying by the number of trees. These lines show that even much shorter models are effective. This result is expected as each added tree improves the model. Specifically, this graph shows that cutting the number of trees by half has a minor effect on the FBC but may dramatically reduce the power consumption and latency.

There are several advantages associated with these embodiments. For example, these embodiments allow modular and flexible usage of invested resources, optimizing a tradeoff between accuracy-provided thresholds on one hand and latency and power consumption on the other hand.

Finally, as mentioned above, any suitable type of memory can be used. Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and wordlines.

A three-dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements in each column. The columns may be arranged in a two-dimensional configuration, e.g., in an x-z plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three-dimensional structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the embodiments described herein can be used alone or in combination with one another.

What is claimed is:

1. A data storage device comprising:
a memory; and
one or more processors, individually or in combination, configured to:
use a tree-based inferencing model to generate a plurality of trees, wherein each tree produces an inference result based on a plurality of read thresholds;
obtain an inferred read threshold by summing the inference results of the plurality of trees; and
read the memory using the inferred read threshold.

2. The data storage device of claim 1, wherein the one or more processors, individually or in combination, are further configured to use the tree-based inferencing model to generate additional trees, wherein the inferred read threshold is obtained by summing the inference results of the plurality of trees and the additional trees, which provides greater accuracy.

3. The data storage device of claim 2, wherein a number of trees in the additional trees is based on a program-erase count.

4. The data storage device of claim 2, wherein a number of trees in the additional trees is based on an environment condition.

5. The data storage device of claim 2, wherein a number of trees in the additional trees is based on a performance requirement.

6. The data storage device of claim 2, wherein a number of trees in the additional trees is based on available resources.

7. The data storage device of claim 2, wherein a number of trees in the additional trees is based on a temperature.

8. The data storage device of claim 2, wherein a number of trees in the additional trees is based on a power consumption.

9. The data storage device of claim 1, wherein the one or more processors, individually or in combination, are further configured to apply performance throttling to allow additional bandwidth for obtaining the inferred read threshold using a full tree-based model.

10. The data storage device of claim 1, wherein the tree-based inferencing model comprises a random-forest gradient boosting prediction model.

11. The data storage device of claim 1, wherein the one or more processors are implemented purely in hardware.

12. The data storage device of claim 1, wherein the memory comprises a three-dimensional memory.

13. In a data storage device comprising a memory, a method comprising:
analyzing operating conditions and/or available resources of the data storage device;
based on the analyzing, determining a number of single read threshold operations;
operating a read threshold calibration unit the determined number of times to provide a read threshold calibration result; and
reading the memory using the read threshold calibration result.

14. The method of claim 13, wherein the determining is performed before performing a calibration operation.

15. The method of claim 13, wherein the determining is performed on-the-fly based on feedback from the read threshold calibration unit.

16. The method of claim 13, further comprising:
after each iteration of the read threshold calibration unit, determining whether to terminate operations or perform another calibration unit iteration, wherein the read threshold calibration result is provided in response to determining to terminate operations.

17. The method of claim 16, wherein determining whether to terminate operations or perform another calibration unit iteration is based on an operating condition, an available resource, and/or feedback from the read threshold calibration unit.

18. The method of claim 13, wherein the read threshold calibration unit comprises a single read threshold calibration unit.

19. The method of claim 13, wherein the method is performed in a dedicated hardware module in the data storage device.

20. A data storage device comprising:
a memory; and
means for:
operating a read threshold calibration unit of the data storage device a plurality of times to provide a read threshold calibration result, wherein the plurality of times is based on operating conditions and/or available resources of the data storage device; and
reading the memory using the read threshold calibration result.
